(19) United States
(12) Patent Application Publication
(10) Pub. No.: US 2009/0188557 A1
(43) Pub. Date: Jul. 30, 2009

(54) Photonic Device And Method Of Making Same Using Nanowire Bramble Layer

(76) Inventors: Shih-Yuan Wang, Palo Alto, CA (US); Philip J. Kuekes, Menlo Park, CA (US); Nobuhiko Kobayashl, Sunnyvale, CA (US); R. Stanley Williams, Portola Valley, CA (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 12/253,206

(22) Filed: Oct. 16, 2008

Related U.S. Application Data
(60) Provisional application No. 61/024,781, filed on Jan. 30, 2008.

(51) Int. Cl. H01L 31/042

(52) U.S. Cl. 136/256; 977/762

(57) ABSTRACT

A photonic device and a method of making the device employ a bramble layer of nanowires having an uneven contour. The photonic device and the method include a first layer of a microcrystalline material provided on a substrate surface and a bramble layer of nanowires formed on the first layer. The photonic device and the method further include a second layer provided on the bramble layer. The nanowires have first ends integral to crystallites in the microcrystalline first layer and second ends opposite to the first ends. Different angular orientations of the nanowires provide the uneven contour of the bramble layer. The second layer has an uneven surface corresponding to the uneven contour of the bramble layer.

### CROSS-REFERENCE TO RELATED APPLICATION

The present application claims priority from provisional application Ser. No. 61/024,781, filed Jan. 30, 2008, the contents of which are incorporated herein by reference in their entirety.

### STATEMENT REGARDING FEDERALLY SPONSORED RESEARCH OR DEVELOPMENT

N/A

### BACKGROUND

1. Technical Field

The invention relates to nanotechnology. In particular, the invention relates to a photonic device and a method of making the device that incorporate a bramble of nanowires.

2. Description of Related Art

Historically, high performance semiconductor devices, especially those with p-n junctions, comprise single crystals of one or more semiconductor materials. Among other things, using such single crystalline materials for semiconductor devices essentially eliminates the scattering of charged carriers (e.g., holes and electrons) at grain boundaries that exist in non-single crystalline semiconductor materials such as polycrystalline semiconductor materials. Such scattering adversely reduces the drift mobility and the diffusion of charged carriers and carrier lifetime, and leads to a degraded performance (e.g., increased resistance) of devices, such as transistors, lasers and solar cells. Even when different semiconductor materials were employed together in a single device, such as in a heterostructure or heterojunction device, single crystalline semiconductor materials are generally chosen based on their respective lattice structures to insure that the structure realized is an essentially single crystalline structure as a whole. Similarly, nanostructures including, but not limited to, nanowires and nanodots are typically nucleated and grows from single crystalline substrates, in part to capitalize on the uniform nature of the lattice of such substrates that provides required crystallographic information for the nanostructures to be grown as single crystals.

In addition to single crystalline semiconductors amorphous and other essentially non-single crystalline semiconductor materials also have been attracting attention, in particular in solar cell and silicon photonics applications. While having the disadvantages associated with multiple grain boundaries, such non-single crystalline semiconductor materials can be considerably cheaper to manufacture than their single crystalline counterparts. In man applications, the lower cost of producing the semiconductor device from non-single crystalline materials may outweigh any loss of performance that may or may not result. Furthermore, using non-single crystalline semiconductor materials for heterostructures can increase the possible combinations of materials that can be used since lattice mismatch is less of a concern with non-single crystalline semiconductors.

For example, heavily doped polycrystalline silicon (Si) is commonly used instead of or in addition to metal for conductor traces in integrated circuits where the heavy doping essentially overcomes the increased resistivity associated with carrier scattering from the multiple grain boundaries. Similarly, polycrystalline Si is commonly used in solar cells where its relatively lower cost outweighs the decrease in performance associated with the nature of the poly crystalline material. Amorphous semiconductor material is similarly finding applications in solar cells and in thin film transistors (TFTs) for various optical display applications where cost generally dominates over concerns about performance.

Unfortunately, the ability to effectively combine non-single crystalline semiconductor materials with single crystalline semiconductor materials to realize semiconductor junction-based devices and heterostructure or heterojunction devices has generally met with little success. In part, this is due to the disruptive effects that joining a single crystalline layer to a non-single crystalline layer has on the physical properties of the single crystalline layer. As such, devices that employ nanostructures as active elements typically use single crystalline materials to interface to single crystalline nanostructures. For example, solar cell devices that incorporate nanowires employ single crystalline materials to form semiconductor junctions.

### BRIEF SUMMARY

In some embodiments of the present invention, a photonic device is provided. The photonic device comprises a first layer of a microcrystalline material on a substrate surface; and a bramble layer of nanowires on the first layer. The nanowires of the bramble layer have first ends integral to crystallites in the first layer and second ends opposite the first ends. The bramble layer has an uneven contour that is provided by different angular orientations of the nanowires. The photonic device further comprising a second layer of a material on the bramble layer that coincides with the uneven contour. The second layer has an uneven surface corresponding to the uneven contour.

In other embodiments of the present invention, a solar cell device is provided that comprises a first layer of a microcrystalline material on a substrate surface; and a bramble layer of nanowires on the first layer. The bramble layer has an uneven contour. The nanowires of the bramble layer have first ends integral to crystallites in the first layer and second ends opposite the first ends. The second ends of the nanowires comprise metallic tips. The solar cell device further comprises a second layer of a material on the uneven contour of the bramble layer, such that the second layer has a corresponding uneven surface for photon capture. The solar cell device further comprises a semiconductor junction located between the first layer and the second layer.

In other embodiments of the present invention, a method of making a photonic device is provided. The method of making comprises providing a first layer of a microcrystalline material on a substrate surface. The method of making further comprises forming a bramble layer of nanowires on the first layer. The nanowires of the bramble layer have first ends integral to crystallites in the first layer and second ends opposite to the first ends. The bramble layer has an uneven contour provided by different angular orientations of the nanowires in the bramble layer. The method further comprises providing a second layer of a material on the bramble layer to follow the uneven contour, such that the photonic device has a corresponding uneven surface for capturing photons.

Certain embodiments or the present invention have other features that are one or both of in addition to and in lieu of the features described hereinabove. These and other features of some embodiments of the invention are detailed below with to reference to the following drawings.

### BRIEF DESCRIPTION OF THE DRAWINGS

The various features of embodiments of the present invention may be more readily understood with reference to the following detailed description taken in conjunction with the accompanying drawings, where like reference numerals designate like structural elements and in which:

FIG. 1 illustrates a side view of a photonic device according to an embodiment of the present invention.

FIG. 2 is a SEM photograph that illustrates a magnified top view of a bramble of nanowires according to an embodiment of the present invention.

FIG. 3 illustrates a flow chart of a method of making a photonic device according to an embodiment of the present invention.

### DETAILED DESCRIPTION

Embodiments of the present invention provide a photonic device that employs a bramble of nanowires as an active photonic component. The bramble of n-nanowires is a tangled plurality of randomly oriented nanowires that are integral at one end to a microcrystalline layer of the photonic device. The bramble is essentially a non-uniform arrays of nanowires that may provide one or both enhanced light absorbing characteristics and enhanced antireflective characteristics to the photonic device in some embodiments. Effectively, the random orientations of the nanowires in the bramble increase the probability that photons will interact with and be absorbed by the nanowires rather than be lost (e.g., reflected) to the surroundings.

Typical antireflective (AR) coatings absorb light in a relatively narrow band of frequencies. In addition such typical AR coatings are generally directionally dependent providing antireflection over only a narrow range of incident angles. In contrast, the bramble of nanowires of the present invention is effectively a nanowire-based antireflector that absorbs a wide band of frequencies of light over a wide range of incident angles. The bramble of nanowires of the nanowire-based antireflector provides overall better light absorbing or trapping ability than typical AR coatings. Thus, in some embodiments, the bramble of nanowires may be useful in a wider range of applications than typical AR coatings. Specifically, the bramble of nanowires may be better suited than typical AR coatings to applications in which light is absorbed such as, but not limited to, when light is to be converted to other forms of energy, in particular, when a light source such as the sun (or multiple light sources) moves over time with respect to a device that is fixed and faces one direction.

The photonic device comprises a microcrystalline material layer that, by definition, has short range atomic ordering. The photonic device further comprises a plurality of nanowires that is integral to (i.e. nucleated and grown from) the microcrystalline material layer, such that the nanowires are single crystalline and have random orientations relative to a plane of the microcrystalline layer (i.e., the bramble). In particular, individual nanowires within the bramble are associated with the short-range atomic ordering of the microcrystalline material layer. Crystallographic information associated with the short-range atomic ordering is transferred to the nanowires during growth of the nanowires. The integral crystal-structure connection at the interface between the microcrystalline material layer and the single crystalline nanowires facilitates using the interface in a variety, of semiconductor junction-related device applications including, but not limited to, optoelectronic device (e.g., photodetectors, LEDs, lasers and solar cells) and electronic device (e.g., tunneling diodes and transistors) applications. Such devices are collectively referred to herein as a ‘photonic device’. The photonic device according to various embodiments herein may have enhanced device performance due to the combined contributions of the integral microcrystalline/nanowire interfaces and the additional surface area provided by the bramble of nanowires.

According to the various embodiments herein, the photonic device comprises a semiconductor junction provided by selective doping within or between the materials or layers. For example, a p-n junction may be formed when the nanowires are doped with an n-type dopant and the microcrystalline material layer is a semiconductor material doped with a p-type dopant. In another example, a p-n junction is formed entirely within the nanowires. In other embodiments, an intrinsic later is formed between a p-region and an n-region to yield a p-i-n junction within the photonic device. For example, a portion of the nanowires may be n-doped while another portion thereof is essentially undoped (e.g., intrinsic) and the microcrystalline layer is p-doped. In other embodiments, multiple p-n junctions, p-i-n junctions and combinations thereof are formed in or between the nanowires and microcrystalline layer(s) as is discussed in more detail below. For simplicity of discussion and not by way of limitation, the term ‘p-n junction’ means herein one or both of the p-n junction and the p-i-n junction unless explicit distinction is necessary for proper understanding.

Further, according to various embodiments, the photonic device may comprise a heterostructure or a heterojunction semiconductor device. For example, semiconductor materials having differing band gaps are employed to respectively realize the single crystalline nanowires and the microcrystalline semiconductor layer of some photonic device embodiments of the present invention. The photonic device that comprises such differing materials is termed a heterostructure photonic device.

Herein, a ‘microcrystalline’ material is defined as a non-single crystalline material that has a structure with short range atomic ordering and as such, the material lacks long-range atomic ordering. In contrast, as used herein, a ‘single crystalline’ material has a crystal lattice structure that is essentially continuous in micrometer scale, as generally defined for a single crystal (i.e., has long-range atomic ordering). A microcrystalline structure is a subset of a polycrystalline structure, which also has short range atomic ordering. The short range atomic order of a microcrystalline structured material has a much smaller extent than the short range atomic order of a polycrystalline structured material. For example, the short range atomic ordering (or order) of a microcrystalline material ranges in extent from about 1 nanometer to about 500 nanometers, in accordance with some embodiments of the present invention. By way of example, a polycrystalline material has short range atomic ordering with a much larger extent that ranges from about 0.01 nanometer to about 100 microns.

Moreover, the short range atomic ordering of a microcrystalline material manifests as multiple, small regions of crystalline material or ‘crystallites’ dispersed within and generally throughout the microcrystalline material. The regions of crystallites may range from clusters of individual crystallites to discrete individual crystallites. Thus, by definition, the microcrystalline material comprises multiple crystallites buried in an amorphous matrix. Adjacent crystallites within the microcrystalline material layer have respective lattices that are essentially randomly oriented with respect to one another. Further, crystallites adjacent to a surface of the microcrystalline material layer are essentially randomly located across the surface. The crystallites in the microcrystalline material essentially define the short range atomic ordering of the material.

The term ‘hetero-crystalline’ is defined herein as a structure comprising at least two different types of structural phases. In particular, herein a hetero-crystalline structure comprises at least a microcrystalline material having crystallites as defined herein, and a single crystalline material that is integral to a crystallite of the microcrystalline material.

With respect to the various embodiments of the present invention, the microcrystalline material, as defined herein, provides a template for nucleation and growth of a single crystalline nanometer-scale semiconductor structure (i.e., ‘nanostructure’). In particular, a crystallite of the microcrystalline material layer provides a nucleation site for growth of a single crystalline nanostructure. The random orientations and distribution of the crystallites in the microcrystalline layer dictate both random orientations and random locations of the nanostructure (i.e., non-uniform array). The nucleation site includes within its scope, but is not limited to, growing one or more nanostructures either from a single crystallite or from an aggregate or cluster of crystallites of the microcrystalline layer, depending on the size of crystallites.

For example, if the size of a single crystallite is ‘large’ compared to the size of a nanostructure, more than one nanostructure may grow from the single crystallite. On the other hand, if the size of a single crystallite is ‘small’ compared to the size of the nanostructure, but many such crystallites aggregate to form a large crystallite area, then a single nanostructure, or even multiple nanostructures, can grow from such a group of crystallites. As used herein, the term crystallite means a range of crystallites from a single crystallite to a group of crystallites aggregated together for the purposes of the various embodiments of the present invention. The grown nanostructure forms an interface with the crystallite where the nanostructure is connected to the crystallite commensurately. As such, the nanostructure is said to be integral to a crystallite of the microcrystalline material. In some embodiments, the structure of the microcrystalline layer material is non-single crystalline (e.g., is the amorphous matrix or another crystallite) in a space between two adjacent nanostructures (i.e., nearest neighbors) that are integral to respective crystallites of the microcrystalline layer.

In some embodiments, the nanostructure is a nanowire. A nanowire is an individual quasi-one dimensional, nano-scale structure typically characterized as having two spatial dimensions or directions that are much less than a third spatial dimension or direction. The presence of the third, greater dimension in nanowires facilitates electron wave functions along that dimension while conduction is quantized in the other two spatial dimensions. As used herein, the term nanowire is defined as a single-crystalline nano-scale structure, as described above, having an axial length (as a major or third spatial dimension), opposite ends and a solid core. A nanowire also may be one of larger than, smaller than and the same size as the crystallite to which it is integrally attached. Moreover, the nanowire may, one or both of have dimensions from lens of nanometers to several hundred nanometers and not have the same dimension along the entire length of the nanowire, for example. As such, the nanowire may have a tapered shape or a non-tapered shape and such shape may be uniform or non-uniform along the axial length of the nanowire. In some embodiments, the nanowire is a semiconductor material.

In some embodiments, the nanostructure is a nanotube that is characterized as having two spatial dimensions or directions that are much less than a third spatial dimension or direction. In some embodiments, the nanotube is a semiconductor material. A nanotube is defined as a single-crystalline nano-scale structure having an axial length (as a major or third spatial dimension), opposite ends and, in contrast to a nanowire, has a hollow core.

In other embodiments, the nanostructure is a nanodot (i.e., a quantum dot (QD)). A nanodot is a single crystalline, quasi zero-dimensional nanostructure that is nanometer-scale (i.e., nano-scale) in all three spatial dimensions or directions and electron wave functions in the nanodot is quantized in all three spatial dimensions. The term ‘nanowire’ may, be used herein to collectively refer the above-described single to crystalline nanostructures unless a distinction is necessary.

Each of the above-mentioned nanostructures may be nucleated and grown from microcrystalline materials, as defined herein, i.e., the microcrystalline material layer, according to the various embodiments herein. An exemplary list of microcrystalline materials useful for the embodiments of the present invention is provided below. As such, a wide variety of materials are available to manufacture the photonic device embodiments of the present invention. The wide variety of available microcrystalline materials may provide a plethora of potential device applications. For example, the photonic device according to various embodiments herein include, but are not limited to, a solar cell, a laser, a photodetector, a light emitting diode (LED), a laser, a transistor and a photodiode.

In addition, using a wide variety of microcrystalline materials may provide cost and manufacturing advantages as well as performance advantages to the photonic device according to some embodiments. For example, a solar cell device that can be manufactured using microcrystalline semiconductor materials with single crystalline nanostructures may be one or both of more cost-effective to make and more efficient compared to conventional solar cells based on single crystalline silicon with single crystalline nanostructures, according to some embodiments, simply due to the fact that expensive single crystal substrates/layers are not necessary and a broader range of materials that are available for solar cell structures. Material and relevant manufacturing costs for microcrystalline semiconductor materials are generally cheaper than those for single crystalline semiconductor materials. Moreover, the greater variety of these available materials mar provide for energy conversion from more of the solar spectrum than previously available, which may improve solar cell efficiency according to some embodiments. In addition, some of the photonic device embodiments of the present invention provide for smaller or more compact construction.

Likewise, incorporating a bramble of nanowires that is a tangled plurality of nanowires with random orientations integral to the microcrystalline material layer provides one or both of increased surface area for photon capture and increased probability that photons will interact with the nanowires or the semiconductor junctions of the photonic device. As such, one or both of light absorption and antireflection may be enhanced. The increased surface area and the increased probability are relative to photonic devices that incorporate predominantly substantially perpendicular nanostructures (e.g., a relatively ordered and uniform array of nanowires) and planar surfaces for photon capture, or that incorporate typical AR coatings. For example, some embodiments of the invention may provide solar cells with greater energy conversion efficiency compared to conventional single crystalline solar cells using predominantly, substantially perpendicular nanowires or using typical AR coatings.

The bramble of nanowires has essentially random nanowire orientations dictated by the random or non-uniform lattice orientations of the crystallites in the microcrystalline material layer. As such, the nanowires of the bramble are referred to as being ‘tangled’ for simplicity of discussion herein. For the purposes of the various embodiments herein, the ‘bramble of nanowires’ is defined as a non-uniform plurality of nanowires that has a vide distribution of angular orientations of the nanowires. The wide distribution of angular orientations is related to the random lattice orientations of the crystallites to which the nanowires of the bramble are coherently attached (i.e., integral to).

The term ‘wide distribution of angular orientations’ of the plurality of nanowires in the bramble means that the nanowires have a broad range of angular orientations where no angular orientation is predominant over other angular orientations (i.e. ‘non-uniform’). In other words, there is no predetermined order and no resulting order to the angular orientations of the nanowires in the bramble. This is in stark contrast to an ordered or uniform array of nanowires, where most of the nanowires are expected to and do grow in a primary direction on a single crystalline material layer or on a layer of uniform nanocrystals or nanoparticles (e.g., in stark contrast to having predominantly substantially perpendicular nanowires alone a [111] direction defined by a single crystal).

As provided below, the nanowires grow integral to a microcrystalline material layer that is on a substrate having a horizontal surface. The microcrystalline layer has a horizontal surface that is generally parallel to the substrate surface. The angular orientations of the nanowires integral to the microcrystalline layer are measured with respect to a horizontal plane parallel to either the substrate surface or the microcrystalline layer surface (hereinafter ‘the horizontal surface’). In particular, the angular orientations of the nanowires are measured herein between a surface normal (i.e., a direction perpendicular) to the horizontal surface and the long axis of the nanowire.

In some embodiments, the wide distribution of angular orientations includes angles that range from zero (0) degrees to 90 degrees. In some embodiments, the wide distribution of angular orientations includes angles that range from greater than zero (0) degrees to less than 90 degrees. In particular, by definition herein, the ‘bramble of nanowires’ comprises no predetermined angular orientations of the nanowires that predominant over other angular orientations in the bramble according to the various embodiments herein.

In some embodiments, the wide distribution of angular orientations is approximated by a broad Gaussian distribution. For example, the vide distribution mats have a mean angular orientation value that ranges from about 30 degrees to about 70 degrees in some embodiments. Ultimately, a randomness (i.e. width) of the distribution is related to a randomness of lattice orientations of the crystallites in the microcrystal line layer.

In contrast, nanowires that grow on a single crystalline material layer or a layer of nanocrystals or nanoparticles are predetermined and substantially uniformly oriented with the uniform crystal lattice orientation of the single crystals (e.g., nanowires are predominantly substantially perpendicular to a [111] lattice direction). Therefore, the angular orientations of nanowires integral to a single crystalline material layer or a layer of nanocrystals or nanoparticles have a negligible distribution of angular orientations relative to the wide distribution of angular orientations of the nanowires integral to a microcrystalline material layer according to the various embodiments of the present invention.

Moreover, while a nanowire may grow integral to a crystallite of a microcrystalline surface with a substantially perpendicular orientation relative to the substrate surface plane, such a substantially perpendicular nanowire in the photonic device occurs randomly (is not predetermined) and does not predominant. In some embodiments, a substantially perpendicular nanowire is not considered a member of the bramble, as defined herein, because it may be a relatively insignificant contributor to enhancing one or both of light absorption and antireflection compared to other oriented nanowires of the bramble.

For the purposes of the various embodiments herein, the article ‘a’ or ‘an’ is intended to have its ordinary meaning) in the patent arts, namely ‘one or more’. For example, ‘a nanowire’ means ‘one or more nanowires’ and as such, ‘the nanowire’ means ‘the nanowire(s)’ herein. Moreover, ‘a crystallite’ means ‘one or more crystallites’ and includes within its scope ‘a group of crystallites’, as defined above. It is irrelevant whether a particular layer is described herein as being on a top or upper side, a bottom or lower side, or on a left side or a right side of other layers of the photonic device. Therefore, any reference herein to ‘top’, ‘bottom’, ‘upper’, ‘lower’, ‘left’ or ‘right’ with respect to the layers is not intended to be a limitation herein. Moreover, examples described herein are provided for illustrative purposes only and not by way of limitation.

The use of brackets ‘[ ]’ herein in conjunction with such numbers as ‘111’ and ‘110’ pertains to a direction or orientation of a crystal lattice and is intended to include directions ‘< >’ within in its scope, for simplicity herein. The use of parenthesis ‘( )’ herein with respect to such numbers as ‘111’ and ‘110’ pertains to a plane or a planar surface of a crystal lattice and is intended to include planes ‘{ }’ within its scope for simplicity herein. Such uses are intended to follow common crystallographic nomenclature known in the art.

In some embodiments of the present invention, a photonic device is provided that comprises a first layer of a microcrystalline material on a substrate surface; a second layer of a material vertically spaced from the first layer; and a bramble of nanowires extending between the first layer and the second layer. The microcrystalline material of the first layer comprises crystallites, as defined herein. Adjacent crystallites within the microcrystalline material layer have respective lattices that are essentially randomly oriented with respect to one another. Further, crystallites adjacent to a horizontal surface of the microcrystalline material layer are essentially randomly located across the surface.

The bramble of nanowires is a plurality of nanowires in a tangled and non-uniform array on the horizontal surface of the first layer that forms a bramble layer with a horizontal extent and an uneven surface or contour. The nanowires have first ends that are integral to the crystallites in the first layer. The nanowires of the bramble plurality further have second ends that are opposite the first ends. The bramble of nanowires is defined above. In some embodiments, a cross-sectional width dimension of the nanowires in the bramble ranges from about 40 nm to about 500 nm. In some embodiments, the width dimension of the nanowires in the bramble is not less than about 100 nm. For photonic device applications, wider nanowires provide better absorption of photons than narrower nanowires in some embodiments. Moreover, the band gap of the nanowire material may be less blue-shifted for wider nanowires than for narrower nanowires in some embodiments.

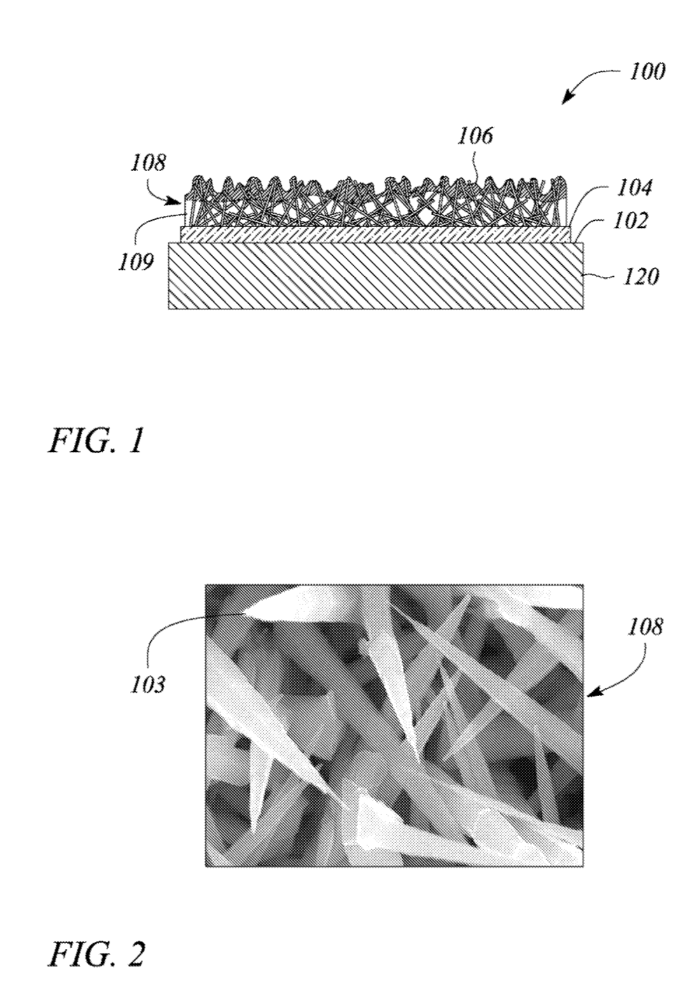

FIG. 1 illustrates a side view of a photonic device 100 according to an embodiment of the present invention. FIG. 2 is a SEM photograph that illustrates a magnified top view of a bramble of nanowires according to an embodiment of the present invention. With respect to FIG. 1, the photonic device 100 comprises a first layer 104 of the microcrystalline material on the substrate surface 102, a bramble layer of nanowires 108 on the horizontal surface of the first layer 104 and a second layer 106 vertically spaced from the first layer 104 by the bramble layer of nanowires 108. The first ends of the nanowires of the bramble 109 are integral to the crystallites in a horizontal surface of the microcrystalline first layer 104, such that the nanowires of the bramble 108 have the random orientations, as defined herein. The nanowires of the bramble 108 further have second ends that are opposite to the first ends. In some embodiments, the second ends of at least some of the nanowires of the bramble 108 are directly connected to the second layer 106. In addition, the second ends of some other nanowires of the bramble 108 are touching other nanowires in the bramble 108 and therefore, are indirectly connected to the second layer 106 in some embodiments.

As mentioned above, the nanowires are integral to crystallites in the first layer 104. By integral to, it is meant that the crystallites of microcrystalline layer and the single crystalline nanowires form an interface where the lattice of the nanowires is coherent with the lattice of the respective crystallites. The coherent lattices of the heterocrystalline materials facilitate charge carrier transport through the interface, for example. The crystallite provides a nucleation site for the epitaxial growth of the single crystalline nanowire during manufacturing of the photonic device 100. As such, the nanowires are also physically anchored to the crystallites of microcrystalline material layer. FIG. 1 illustrates the bramble of nanowires 108 anchored at a first end of the nanowires to the crystallites of the first layer 104.

Moreover, since the crystallites of the microcrystalline material have randomly oriented crystal lattices in adjacent crystallites, the direction of nanowire growth is essentially random. FIG. 1 further illustrates the various random and non-uniform directions of the nanowires in the bramble 108 by way of example. Some of the nanowires of the bramble 108 may be tangled with other nanowires. In some embodiments, some of the nanowires of the bramble 108 intersect one another during growth such that lattices of these individual nanowires merge with one another. Therefore, some nanowires of the bramble of nanowires 108 are essentially ‘integrally tangled’ with other nanowires of the bramble 108, in some embodiments. FIG. 2 provides a magnified view of a portion of the tangled plurality of nanowires of the bramble 108 by way of example.

Furthermore, the crystallites are randomly located in the surface of the first latter 104 and not all crystallites in the surface will nucleate growth of a nanowire. As such, growth of the nanowires of the bramble 108 in any particular location on the horizontal surface of the first layer 104 is also essentially random. FIG. 1 further illustrates the random locations of the nanowires of the bramble 108 grown on the horizontal surface of the first layer 104 by way of example.

The nanowires in the bramble 108 of the photonic device of FIG. 1 have a vide distribution of angular orientations, as defined above. The bramble of nanowires 108 forms the bramble layer 108 on the first layer 104 that has a horizontal extent and an uneven contour. By uneven contour it is meant that a horizontal surface of the bramble latter 108, which is generally parallel to the horizontal surface of both the microcrystalline first layer 104 and the substrate 120, is non-planar, irregular and bumpy. In some embodiments, the uneven contour comprises second ends of some of the nanowires, axial portions of others of the nanowires, and both second ends and axial portions of still other nanowires of the bramble. As such, the uneven contour is dictated and provided by the different angular orientations of the nanowires that represent the wide distribution of angular orientations in the bramble. The terms ‘bramble’ and ‘bramble layer’ are intended to have the same meaning and are used interchangeable herein.

The second layer 106 is adjacent to and on the uneven horizontal surface of the nanowire bramble layer 108. The second layer 106 coincides with or conforms to the uneven contour of the bramble layer 108, such that the uneven contour of the bramble layer 108 is preserved at the photonic device 100 surface. As such, the second layer 106 has an uneven surface that essentially corresponds to the uneven contour of the bramble layer 108. The uneven surface of the second layer 106 provides more surface area to the photonic device 100 to capture photons (i.e., to deflect the light to regions of the bramble layer 108 for the absorption of light, for example). In some embodiments, the uneven surface of the second layer 106 behaves as a light trap and captures photons very effectively. As such, very few photons are reflected from the surface.

In some embodiments, the second layer 106 is a material that is or is rendered transparent or semi-transparent to electromagnetic radiation in at least the visible, UV and IR spectrums (i.e., optically transparent). By ‘rendered’ optically transparent, it is meant that the material is provided in very thin layer such that photons of light penetrate the second layer 106, as opposed to being an inherently optically transparent material. In some embodiments, the second layer 106 is or is rendered electrically conductive (e.g., an ohmic contact metal or a doped semiconductor, respectively). In some embodiments, the second ends of the nanowires in the bramble 108 comprise metallic tips that are not illustrated in FIG. 1. A metallic tip 103 is illustrated in the magnified view of the nanowire bramble 108 in FIG. 2 by way of example. In some embodiments, the metallic tips on the second ends of some of the nanowires in the bramble layer 108 facilitate an electrical connection with the second layer 106.

Materials of die second layer 106 include, but are not limited to, a semiconductor, a metal and a metal oxide. For example, the second layer 106 mats comprise indium tin oxide (ITO) or another transparent conductive oxide (TCO) (e.g., fluorine doped tin oxide, SnO₂:F, or aluminum doped zinc oxide, ZnO:Al). In another example, the second layer 106 may comprise a metal that is rendered optically transparent (e.g., silver, gold or aluminum provided in an essentially continuous very thin layer such as, but not limited to, a monolayer). In vet another example, the second layer 106 may comprise a relatively thin layer of an optically transparent semiconductor (e.g., polysilicon) with a sufficiently high doping level to render it conductive. In some embodiments, the second layer 106 comprises one or both of a microcrystalline silicon and a transparent conductive oxide, such as indium tin oxide (ITO), to allow maximum transmission of light to the nanowires. The second layer 106 material includes materials that have one of no crystallographic structure (e.g., amorphous), a microcrystalline structure (i.e., having short range atomic order, as defined herein), a polycrystalline structure (i.e., having short range atomic order of relatively greater extent than a microcrystalline structure, as defined herein), and a single crystalline structure (i.e., having relatively long range atomic order), according to the various embodiments herein.

A microcrystalline material of the first latter 104 includes, but is not limited to, an insulator, a semiconductor, a metal and a metal alloy provided on the substrate as a thin film. For the purposes of the various embodiments of the present invention, the microcrystalline material used herein is a semiconductor material. In some embodiments, one or both of a metal material and metal alloy material may be used as a microcrystalline layer in the present invention due to their non-insulative character (i.e., an inherent non-insulator or inherently electrically conductive), depending on the device application.

The microcrystalline semiconductor materials include, but are not limited to, Group TV semiconductors, compound semiconductors from Group III-V and compound semiconductors from Group II-VI having a microcrystalline structure, as defined herein. For example, the first layer 104 may comprise silicon (Si), germanium (Ge) or gallium arsenide (GaAs) in a microcrystalline film. In another example, the first layer 104 may comprise a hydrogenated silicon (Si:H) microcrystalline film. When both the first layer 104 and the second layer 106 are semiconductor materials, the semiconductor material of the first layer 104 may be the same as or different from the semiconductor material of the second layer 106, depending on the embodiment. However, the semiconductor material of the first layer 104 has a microcrystalline structure whereas the structure of the second layer 106 semiconductor material may be any of single crystalline, microcrystalline, polycrystalline or amorphous, as mentioned above.

In some embodiments, the nanowires comprise a single crystalline semiconductor material. Single crystalline semiconductor materials of the nanowires also independently include, but are not limited to, Group IV semiconductors, compound semiconductors from Group III-V and compound semiconductors from Group II-VI. Therefore, the semiconductor material of the nanowires in the bramble 108 may be the same as or different from the semiconductor material of one or both of the first layer 104 and the second layer 106, depending on the embodiment, but the semiconductor material of the first layer 104 has a microcrystalline structure, as provided above. For example, the semiconductor material of the first layer 104 may be microcrystalline Si:H, the semiconductor material of the nanowires may be single crystalline indium phosphide (InP), and the semiconductor material of the second layer 106 may be an amorphous indium tin oxide (ITO), depending on the embodiment.

In some embodiments, one or both of the single crystalline nanowires and the microcrystalline first layer 104 are independently a material that forms one of a zincblende crystal structure and a diamond crystal structure. For example, zincblende and diamond crystal structures may be more conductive to a metal-catalyzed nanowire growth process, as further described below, than one or both of a wurtzite crystal structure and a rock-salt crystal structure. In some embodiments, one or both of the single crystalline nanowires and the microcrystalline first layer 104 independently excludes materials that form one of the wurtzite crystal structure and the rock-salt crystal structure. A description of crystal lattices and crystal structures can be found in the textbook by Sze, S. M. Physics Semiconductor Devices, Second Edition, John Wiley & Sons, Inc. 1981, on pp. 8-12 and in Appendix F. pg. 848, for example.

In some embodiments, concomitant with a choice of the semiconductor materials independently used in the first layer 104, the bramble of nanowwires 108 and the second layer 106, depending on the embodiment, is a respective energy band gap of the respective materials. In some embodiments of the photonic device 100, the energy band gap of the bramble of nanowires 108 is different from the energy band-gap of one or both of the first layer 104 and the second layer 106. In some embodiments, the energy band gap of the first layer 104 is different from the energy band gap of the second layer 106. In other embodiments, the energy band gaps of the first layer 104 and the second layer 106 are the same. Using materials with different energy band gaps makes the photonic device 100 a heterostructure device.

In some embodiments, the photonic device 100 further comprises an encapsulant material 109 in which the plurality of nanowires is partially embedded, such that the uneven surface of the bramble layer 108 is preserved. By partially embedded, it is meant that a portion of the nanowxires are exposed at a surface of the encapsulant material 109 (i.e., extend through the encapsulant layer 109) to preserve the uneven surface and to allow most or at least some of the nanowires to make contact with the second layer 106. As such, the second ends of some of these nanowires and axial portions of these and other nanowires are exposed by the encapsulant material 109 for contacting with the second layer 106.

The encapsulant material 109 is an insulator material that is one of transparent and semi-transparent to electromagnetic radiation in one or more of visible, UV and IR spectrums. In some embodiments, the encapsulant material 109 includes, but is not limited to, one or more of an oxide, a nitride and a carbide of any of the semiconductor materials listed above. For example, the encapsulant material 109 may be one or more of silicon dioxide, silicon nitride or silicon carbide. In other embodiments, the encapsulant material 109 may be one or more of an oxide, a nitride, and a carbide of a metal, such as titanium or gallium, for example. In some embodiments, the encapsulant material 109 is an organic insulator material that includes, but is not limited to, a poly mer that can withstand device processing temperatures above about 100° C. For example, the polymer insulator material may be polyimide.

In some embodiments, the photonic device 100 may further comprise electrical contacts (not illustrated) that are separately connected to the first layer 104 and the second layer 106. The electrical connection created by the electrical contacts facilitates accessing the nanowires at opposite surfaces of the bramble layer 108. In some embodiments, an electrical contact is associated with one of the first layer 104 and the second layer 106, while the other layer 104, 106 is electrically conductive and provides an electrical connection in an of itself. In other embodiments, both of the first layer 104 and the second layer 106 are electrically conductive and function as their own electrical contacts (i.e., electrodes). The electrical contacts are made from a material that includes, but is not limited to, a conductive metal and a semiconductor material that is doped to provide the electrical conductivity for the photonic device 100 application. In some embodiments, the material of the electrical contacts is either transparent or semi-transparent to electromagnetic radiation in one or more of visible. UV and IR spectrums. For simplicity of discussion, the term ‘optically transparent’ is used herein to mean either transparent or semi-transparent to electromagnetic radiation in one or more of visible, UV and IR spectrums.

The photonic device 100 illustrated in FIG. 1 is exemplary of a solar cell in some embodiments. For example, photons pass through the greater surface area of the uneven surface of the photonic device 100 (i.e., second layer 106) and are captured in the bramble layer of nanowires 108. The bramble layer of nanowires 108 facilitates one or both of the capture of a photon in the tangled nanowire plurality and the likelihood that the photon will interact with a p-n junction associated with the bramble layer 108 and generate an electron-hole pair. The first layer 104 and the second layer 106 have low contact resistance to the nanowires 108 and facilitate the extraction of an electric current. Generation of an electric current (i.e., photocurrent) occurs when the electrons and holes generated by photon absorption at the nanowires 108 move away from the p-n junction. For example, the electrons move away in a first direction (e.g., toward the first layer 104) and the holes move away in a second, opposite direction (e.g., toward the second layer 106) as a result of an electric field gradient associated with the p-n junction.

In some embodiments, the uneven surface of the solar cell device 100 facilitates enhanced photon capture or light collection. In some embodiments, the bramble of nanowires 108 facilitates one or both of enhanced light absorption and enhanced antireflection of the light. As such, some embodiments of the solar cell device 100 may provide better light conversion efficiency, and therefore, is more efficient as a solar cell than a solar cell without one or both of the uneven surface for photon capture and the bramble of nanowires. For example, the solar cell device 100 may be more efficient than a solar cell with a planar surface to capture photons. In another example, the solar cell device 100 may be more efficient and mechanically robust than a solar cell with a uniform array of nanowires (i.e., having a negligible distribution of angular orientations). As such, the solar cell device 100 may be more efficient and mechanically robust than a solar cell with substantially perpendicular nanowires bridging between planar horizontal electrodes of the device that predominate in the solar cell, for example.

The photonic device 100 embodiment illustrated in FIG. 1 is also exemplary of a photodetector device in some embodiments. Photons of light penetrate the increased surface area of the uneven surface of the photodetector device (i.e., the second layer 106) and are detected by the bramble of nanowires 108. The uneven surface facilitates the capture of photons or the collection of light. The bramble of nanowires 108 facilitates one or both of antireflection of light and light absorption at a p-n junction of the photodetector device 100. For example, the nanowires of the bramble layer 108 may be undoped and the microcrystalline first layer 104 and the second layer 106 are alternately n-doped or p-doped. Absorption at the p-n junction may result in the formation of an electron-hole pair within the p-n junction. Movement of the electron and hole in respective separate directions away from the junction results in a photocurrent associated with the photodetector device 100.

In some embodiments, the photodetector device 100 is more sensitive to light and therefore, more efficient as a photodetector than a photodetector without one or both of the uneven surface and the bramble layer of nanowires. For example, the photodetector device 100 may be more efficient and mechanically robust than a photodetector with a planar photon capture surface. Moreover, the photodetector device 100 may be more efficient and mechanically robust than a photodetector with a relatively uniform array of nanowires having a substantially uniform angular orientation (i.e., a negligible distribution of angular orientations), for example. As such, the photodetector device 100 may be more efficient and mechanically robust than a photodetector with substantially perpendicular nanowires bridging between the planar horizontal electrodes of the device that predominate in the photodetector, for example.

In some embodiments, the bramble layer of nanowires 108 is a nanowire-based antireflector 108 for devices that convert light to other forms of energy including, but not limited to, current (e.g., photonic device 100) and heat (e.g., a blackbody radiator). A dense population of randomly oriented nanowires in the bramble layer 108 absorbs light in a wide band of optical frequencies and over a wide range of incident angles, such that negligible light is reflected from the bramble layer 108. In some embodiments, the bramble layer 108 absorbs light in one or both of essentially frequency independent and essentially incident angle independent (e.g., isotropic) manner. Thus, the bramble layer of nanowires 108 is an efficient nanowire-based antireflector 108 with broad application compared to tropical antireflective coatings, for example.

In some embodiments, the photonic device 100 further comprises a horizontal substrate 120 that has the aforementioned substrate surface 102, as illustrated in FIG. 1. The substrate 120 is adjacent to the first layer 104, as illustrated in FIG. 1. The substrate 120 provides mechanical support to the photonic device 100. In some embodiments, the function of the substrate 120 is to provide mechanical support to at least the first layer 104. In other embodiments, the substrate 120 may provide additional functionality including, but not limited to, an electrical interface to the photonic device 100 and optical transparency. In general, a broad range of materials are useful as the substrate 120 for the photonic device 100 depending on the embodiment herein.

For example, the material of the substrate 120 includes, but is not limited to, a glass, a ceramic, metal, a plastic, a polymer, a dielectric and a semiconductor. A substrate material useful for the various embodiments herein includes materials that have one of no crystallographic structure (e.g., amorphous), a microcrystalline structure (i.e., having short range atomic order, as defined herein), a polycrystalline structure (i.e., having short range atomic order of relatively greater extent than a microcrystalline structure, as defined herein), and a single crystalline structure (i.e., having relatively long range atomic order). In some embodiments, the substrate material is chosen at least for its ability to withstand manufacturing temperatures at or above about 100 degrees centigrade (° C.). In various embodiments, the substrate 120 may be one of rigid, semi-rigid and flexible, depending on specific applications of the photonic device 100. Moreover, the substrate 120 may be one of reflective, opaque, transparent and semi-transparent to electromagnetic radiation in one or more of visible, ultra-violet (UV) and infra-red (IR) spectrums (i.e., ‘optically transparent’), depending on the application of the photonic device 100.

In some embodiments (not illustrated), the photonic device 100 may further comprise another bramble of nanowires on the second layer 106 of the photonic device in FIG. 2, wherein the second layer 106 is one of a microcrystalline material and an amorphous material. The nanowires of the additional bramble layer are integral to crystallites in the microcrystalline or amorphous second layer 106 in much the same way as described above for the nanowires or the bramble 108 and the first layer 104. As such, a multilayer device structure that comprises multiple alternating layers of one or both of microcrystalline and amorphous materials and the single crystalline nanowire bramble layers in a vertically stacked relationship are within the scope of the various embodiments of the present invention. In some embodiments of the multilayer device structure, one or more of the layers of the microcrystalline and amorphous materials are optically transparent.

According to the various embodiments herein, one or more of the first latter 104, the second layer 106 and the nanowires of the bramble 108 of the photonic device 100 are doped with a dopant material to provide a level of electrical conductivity to the respective lax ers or structures. In some embodiments, the photonic device 100 further comprises a semiconductor junction. For example, in one or more of a solar cell application and a photodetector application, the photonic device 100 comprises a p-i-n junction, in some embodiments. In another example, in one or more of an LED application and a laser application, the photonic device 100 comprises one or both of a p-n junction and a p-i-n junction, in some embodiments. In other examples, the photonic device 100 may comprise a Schottky junction instead of or in addition to the p-n junction.

Depending on the embodiment, the p-n junction may be located one or more of in the nanowires of the bramble 108, between the nanowires of the bramble (e.g., when integrally fused during growth), between the nanowires of the bramble and the first layer 104, between the nanowires of the bramble and the second layer 106, and between the first layer 104 and the second layer 106, and includes a p-i-n junction within its scope. For example, the first layer 104 and the second layer 106 may comprise a p-type dopant material and the bramble of nanowires 108 may comprise an n-type dopant material. In another example, the first layer 104 may comprise a p-type dopant material and the second layer 106 may comprise an n-type dopant material while the bramble of nanowires 108 are undoped (i.e., a p-i-n junction).

In another example, the first layer 104 and the nanowires of the bramble 108 may be p-doped, while the second layer 106 is n-doped. A p-n junction is formed between the nanowires of the bramble 108 and the second lawyer 106. In another example, the bramble of nanowires 108 comprises both a p-type dopant material and an n-type dopant material in separate regions along the axial length of the nanowires. It is within the scope of the embodiments for the dopant types of any of the examples herein to be reversed among the layers 104, 106 and the respective nanowires of the bramble layer 108.

In some embodiments, the second layer 106 man be an ohmic contact metal, or the second layer 106 may comprise a semiconductor with a dopant type that is either the same as or different from the dopant type of one or both of the first layer 104 and the bramble of nanowires 108, depending on the example. Other variations on the location and doping of the photonic device 100 exist and are within the scope of the present invention. For example, the nanowires of the bramble 108 may incorporate one or both of more than one p-n junction or more than one p-i-n junction.

Moreover, the level of doping in each layer may be the same or different. The variation in dopant level may yield a dopant gradient, for example. In an example of differential doping, one or both of the first layer 104 and the second layer 106 may be heavily doped to yield a p+ region providing a low resistivity within the respective layer 104, 106 while the adjacent axial region of the nanowires may be less heavily P-doped to yield a p region. Various p-n junctions are described and illustrated in co-pending U.S. patent application Ser. No. 11/681,068, which is incorporated herein by reference in its entirety.

For example, in some embodiments of a solar cell application (not illustrated), the photonic device 100 further comprises a plurality of different single crystalline semiconductor bramble layers and a plurality of different microcrystalline semiconductor material layers, arranged as described above in a multilayer device structure. The device further comprises a plurality of p-n junctions, located according to any of the p-n junction embodiments described above. A spatial arrangement of the plurality of p-n junctions and the variety and random orientations of bramble layers of nanowires cover a large effective area over which sun light is received and captured by the multilayer photonic device. Furthers the different material layers of the multilayer device structure convert a wide range of the solar spectrum. Such a multilayer, multi-junction solar cell device has increased efficiency and performance that may correspond to the increased number of different layers, nanowire bramble layers and p-n junctions.

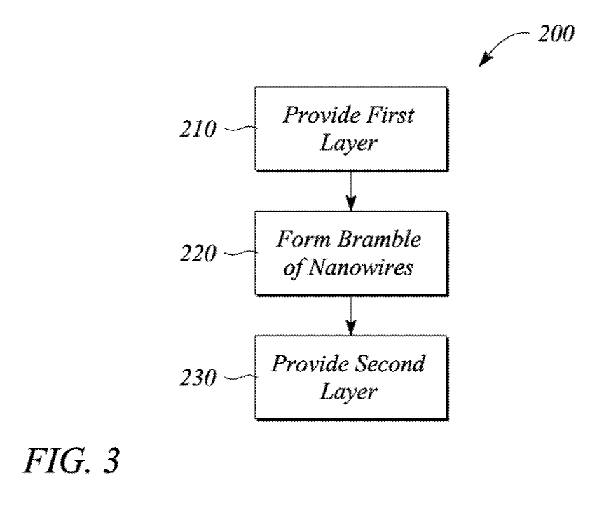

In another embodiment of the present invention, a method of making a photonic device is provided. FIG. 3 illustrates a flow chart of a method 200 of making a photonic device according to an embodiment of the present invention. The method 200 of making the photonic device comprises providing 210 a first layer of a microcrystalline material on a surface of a substrate. The method 200 of making further comprises forming 220 a bramble of nanowires on the first layer; and providing 230 a second layer of a material on the bramble of nanowires, such that the first layer and the second layer are vertically spaced apart by the bramble. The bramble is a non-uniform plurality of nanowires having first ends integral to crystallites in the microcrystalline first latter. The nanowires of the plurality further have second ends that are opposite the first ends. The second ends of the nanowires are one or more of in contact with other nanowires, in contact with the second layer and not in contact with either the second layer or other nanowires.

The non-uniform plurality of nanowires forms a bramble layer having a horizontal extent with an uneven contour on the horizontal surface of the first layer. The second layer is provided 230 on the bramble layer to follow the contours of the uneven bramble layer such that the uneven contour is preserved. As such, most or at least some of the nanowires of the non-uniform plurality make an electrical connection to the second layer. Some of the nanowires make electrical contact with the second layer directly with one or both of a respective second end of the nanowires and an axial portion of the nanowires. Moreover, some of the nanowires of the bramble are tangled with other nanowires of the bramble. As such, some of the nanowires electrically connect to the second layer indirectly through direct contact with nanowires that make direct electrical contact with the second layer. The nanowires of the bramble have random orientations, as defined herein. The random orientations of the nanowires of the bramble layer are dictated by the randomness of the crystallites in the microcrystalline material of the first layer, also as defined herein. As such, the nanowires of the bramble have a wide distribution of angular orientations, also as defined herein. In some embodiments, a photonic device similar to the photonic device 100 illustrated in FIG. 1 is manufactured using the method 200 of making a photonic device.

In some embodiments, providing 210 a first layer of a microcrystalline material comprises depositing a semiconductor material on the surface of the substrate in a microcrystalline film. In some embodiments, the microcrystalline film of a semiconductor material is deposited using a chemical vapor deposition (CVD) process, such as plasma enhanced CVD (PECVD), and a semiconductor source gas or gas mixture. For example, a microcrystalline silicon film may be deposited onto a silicon dioxide surface of a substrate using PECVD at a temperature ranging from about 100° C. to about 300° C. and a source gas mixture or silane and hydrogen. In this example, the first layer is a microcrystalline hydrogenated silicon film. Other methods of deposition of microcrystalline films according to the present invention include, but are not limited to, physical vapor deposition, such as sputtering or vacuum evaporation. The first layer is formed 210 with multiple crystallites of varying sizes, as defined above for the microcrystal line structure or layer. A crystallite near the surface in the first layer provides a template for nucleating with a nanowire.

In some embodiments, forming 220 a bramble of nanowires comprises growing a plurality of nanowires from the crystallites in the microcrystalline material of the first layer. In some embodiments, the nanowires of the bramble are grown using a metal-catalyzed growth process to form 220 the bramble, such that the nanowires comprise a metal nanoparticle catalyst at the tip of the second ends (i.e. a metallic tip). The grown nanowires have random orientations relative to the horizontal surface of the microcrystalline first layer (and therefore, the substrate surface) and form 220 a bramble layer of nanowires that are integral to the first layer crystallites, as defined herein. The bramble layer has a horizontal span and an uneven contour due to the tangled and non-uniform plurality of the nanowires in the bramble. As defined above, the bramble layer has a wide distribution of angular orientations of the nanowires.

By definition, the wide distribution of angular orientations in the bramble negates any one angular orientation from predominating over any other angular orientation. The bramble is a tangled and non-uniform array of nanowires. As described above for the photonic device 100 embodiment, while a nanowire may grow substantially perpendicular to a horizontal plane parallel to the substrate surface as a part of the bramble, the occurrence of a substantially perpendicular nanowire is random. Moreover, in some embodiments, a substantially perpendicular nanowire contributes less significantly to the effect that the non-uniform plurality of nanowires in the bramble have on the photonic device performance. Therefore, in some embodiments, a substantially perpendicular nanowire is not considered a member of the bramble.

After the bramble of nanowires is formed 220 as a bramble layer, the second layer of a material is provided 230 on the uneven surface of the bramble layer, such that the contours of the bramble layer surface is preserved. As such, the second layer has a corresponding uneven surface. The second layer is provided 230 using a deposition technique including, but not limited to, evaporative sputtering, that deposits the second layer of material to follow the contours of the uneven surface of the bramble layer. The uneven surface of the second layer provides the photonic device made by the method 200 with more surface area for photons to initially contact the photonic device and be captured. The second layer is an optically transparent material that allows photons to readily penetrate and pass through the second layer to contact the bramble layer.

As such, at least some of the nanowires in the bramble layer make direct electrical contact with the second layer one or both of with the second ends of the nanowires and axial portions of the nanowires. In some embodiments, most of the nanowires in the bramble layer make contact with the second layer through direct to electrical contact and indirect electrical contact, both as described above. In some embodiments where the nanowires have a metallic tip on the second ends, the metallic tips on the nanowires facilitate the electrical connections ultimately to the second layer. The tangled plurality of nanowires in the bramble layer provides more opportunity for the photons to make contact with and be absorbed by nanowires and therefore, enhances is the performance of the photonic device in some embodiments.

In some embodiments, the nanowires are grown on the first layer of microcrystalline material using an epitaxial growth process to achieve a single-crystalline semiconductor nanostructure. Nanowires are grown epitaxially using a variety of techniques including, but not limited to, catalytic growth using vapor-liquid-solid (VLS) growth, catalytic growth using solution-liquid-solid (SLS) growth, and non-catalytic growth using vapor-phase epitaxy. Catalytic growth is further characterized by being either metal catalyzed or nonmetal catalyzed. The growth is performed in a chemical vapor deposition (CVD) chamber in a controlled environment using a gas mixture comprising nanowire source materials. During catalytic growth, nanowires grow with certain crystal directions of respective crystallites in the microcrystalline layer. Since the microcrystalline structure of the first layer comprises crystallites with random crystal orientations, the nanowires will grow in random directions from some crystallites at the surface of the microcrystalline layer.

For nanodots, the growth is stopped almost immediately after it is started, in some embodiments. In other embodiments, the nanodots form spontaneously on the microcrystalline layer by so-called self-organized growth driven by strain associated with the difference in lattice constants between the nanodots and the crystallites in the microcrystalline layer. In some embodiments, a nanodot may be grown from the crystallites as a ‘seed’ from which a nanowire or nanotube is subsequently groan.

Typical catalyst materials are metals and nonmetals. Metal catalyst materials include, but are not limited to, titanium (Ti), platinum (Pt), nickel (Ni), gold (Au), gallium (Ga), and alloys thereof. Nonmetal catalyst materials include, but are not limited to, silicon oxide (SiOₓ), where x ranges from about 1 to less than 2, for example. Typical nanoparticle catalysts corresponding to Ti and Au catalyst materials, for example, are respectively titanium silicide (TiSi₂) and gold-silicon (Au—Si) alloy.

In some embodiments, forming 220 a bramble of nanowires comprises using a catalytic growth process to provide the bramble layer. In some of these embodiments, a metal-catalyzed growth process is used that comprises using vapor-liquid-solid (VLS) growth and a metal nanoparticle catalyst. Nanoparticle catalysts are formed on a surface of the microcrystalline layer using any one of a variety of deposition processes. In some embodiments, a nucleation layer of a catalyst material is deposited on the surface by various types of physical and chemical vapor deposition techniques. The nucleation layer is annealed into activated nanoparticle catalysts on the surface of the microcrystalline lawyer, for example. The activated nanoparticle catalysts are discontinuous on the surface relative to the nucleation layer. In other embodiments, a metal catalyst material is deposited using electrochemical deposition using a deposition solution comprising a salt of the metal catalyst material. In some embodiments, excess catalyst material may be removed from the surface of the microcrystalline layer, for example, by annealing.

In other embodiments, the catalyst particles are suspended in a solution and deposited on the surface of the microcrystalline layer as droplets. For example, gold colloidal particles dispersed in toluene may be delivered to the surface of the microcrystalline layer in multiple droplets using a pipette, or an inkjet printhead. The toluene may be pumped away in vacuum, leaving the gold nanoparticles on the surface to act as catalysts for the VLS growth of the nanowires. In this example, the gold colloidal particles have a diameter of about 10 nm and a nominal concentration of about 5×10¹⁵ ml⁻¹.

Nanowire growth is initiated in a CVD reaction chamber using a gas mixture of a nanowire source material that is introduced into the chamber at a growth temperature and using nanoparticle catalysts that are located on the crystallites at the surface of the microcrystalline layer. The activated or nucleating nanoparticle catalyst accelerates decomposition of the nanowire source material in the gas mixture, such that adatoms resulting from decomposition of the nanowire source material diffuse through or around the nanoparticle catalyst, and the adatoms precipitate on the microcrystalline layer surface. In particular, the adatoms of the nanowire material precipitate between the nanoparticle catalyst and the surface of the microcrystalline layer at the respective crystallites to initiate nanowire growth. Moreover, catalyzed grouch of the nanowire is continued with continued precipitation at the nanoparticle-nanowire interface. Such continued precipitation causes the nanoparticle catalyst to remain at the tip of the free end of the growing nanowire. As mentioned above, the metal-catalyzed growth process provides a metallic tip on the second end of the nanowire. The metallic tip comprises is the metal nanoparticle catalyst used to catalyze the growth process.

For example, indium phosphide (InP) nanowires may be grown on the microcrystalline hydrogenated silicon film by metalorganic CVD (MOCVD). In this example, trimethylindium and phosphine in a hydrogen carrier gas are used at a growth pressure of about 76 Torr and temperature of about 430° C. Moreover, a gold-silicon alloy material is used as the metal nanoparticle catalyst. The InP nanowires are anchored to the crystallites in the microcrystalline silicon film at the first end and have metallic lips comprising gold at the second end in this example.

In some embodiments, the method 200 of making further comprises doping one or more of the first layer, the second layer and the nanowires, depending on the embodiment. Doping provides a level of electrically conductivity to the material. Moreover, doping forms a p-n junction generally located between the first layer and the second layer. In some embodiments, the p-n junction is any of the p-n junctions (including p-i-n junctions) described above for the semiconductor junction of the photonic device 100. The dopant materials used and the dopant levels achieved are dependent on the photonic device application and not considered a limitation herein. The method 200 may further comprise forming one or more of a Schottky junction, a heterostructure and a heterojunction between the bramble of nanowires and the microcrystalline layer, depending on the embodiment.

In some embodiments, the method 200 of making further comprises embedding a portion of the bramble layer of nanowires in an encapsulant material. Before providing 230 the second layer, the bramble layer is partially embedded in the encapsulant material, such that the uneven surface of the bramble layer is exposed above a surface of the encapsulant material. The second layer of material is subsequently provided 230 on both the encapsulant surface and the exposed uneven surface of the bramble layer to follow the contours of the uneven bramble layer surface. The second to layer makes contact with the exposed portions of the nanowires of the bramble layer. The encapsulant material is optically transparent and an insulator, such that it does not interfere with photonic reactions with the nanowires.

In some embodiments, the method 200 of making further comprises providing an electrical connection to electrically access the bramble of nanowires. In some embodiments, an electrical contact is formed adjacent to the first layer, such that the nanowires of the bramble layer are electrically accessible at the first ends of the nanowires. In some embodiments, another electrical contact is formed adjacent to the second layer, such that the nanowires of the bramble layer, which are in electrical contact with the second layer, are electrically accessible. As such, each of the first lather, the second layer and the bramble of nanowires comprises a level of electrical conductivity achieved either through doping or using inherently electrically conductive materials. The electrical connection is formed using a deposition method and either a conductive metal material (e.g., an ohmic contact metal) or an appropriately doped semiconductor material, as described above. For example, deposition methods including, but not limited to, sputtering and evaporation may be used.

Thus, there have been described various embodiments of a photonic device and a method of making a photonic device employing a bramble of nanowires integral to a microcrystalline material. It should be understood that the above-described embodiments are merely illustrative of some of the many specific embodiments that represent the principles of the present invention. Clearly, those skilled in the art can readily devise numerous other arrangements without departing from the scope of the present invention as defined by the following claims.

What is claimed is:

1. A photonic device comprising:
a first layer of a microcrystalline material on a substrate surface;
a bramble layer of nanowires on the first layer, the nanowires of the bramble layer having first ends integral to crystallites in the first layer and second ends that are opposite the first ends, the bramble layer having an uneven contour, different angular orientations of the nanowires providing the uneven contour; and
a second layer of a material on the bramble layer that coincides with the uneven contour, the second layer having a corresponding uneven surface.

2. The photonic device of claim 1, further comprising an encapsulant material that partially embeds the bramble layer, such that a portion of the nanowires forming the uneven contour extends through the encapsulant material.

3. The photonic device of claim 2, wherein the second layer is on the encapsulant material, the second layer being in contact with the portion of the nanowires extending through the encapsulant material.

4. The photonic device of claim 2, wherein the encapsulant material is optically transparent.

5. The photonic device of claim 1, wherein the microcrystalline material of the first latter is a semiconductor material, the nanowires of the bramble layer being a single-crystalline semiconductor material, the second layer being optically transparent.

6. The photonic device of claim 1, Wherein the second ends of some of the nanowires are directly connected to the second layer, the second ends of others of the nanowires being indirectly connected to the second layer.

7. The photonic device of claim 1, wherein the second ends of the nanowires comprise metallic lips.

8. The photonic device of claim 1, wherein the substrate and the second layer are independently a material having a structure that is one of microcrystalline, polycrystalline and amorphous.

9. The photonic device of claim 1, wherein the first layer and the second layer are independently both optically transparent the substrate being optically transparent.

10. The photonic device of claim 1, wherein the bramble layer of nanowires is a nanowire-based antireflector, the nanowire-based antireflector being light absorptive both in a wide band of frequencies and over a wide range of incident angles, such that negligible light is reflected from the photonic device.

11. The photonic device of claim 1, wherein a semiconductor junction is located one or more of in the nanowires, between the first layer and the nanowires, between the second layer and the nanowires, and between the first layer and the second layer.

12. The photonic device of claim 1, wherein the photonic device is one of a photodetector and a solar cell.

13. A solar cell device comprising
a first layer of a microcrystalline material on a substrate surface;
a bramble layer of nanowires on the first layer, the bramble having an uneven contour, the nanowires of the bramble layer having first ends integral to crystallines in the first layer and second ends opposite the first ends, the second ends of the nanowires comprising metallic tips;
a second layer of a material on the uneven contour of the bramble layer, such that the second layer has a corresponding uneven surface for photon capture; and
a semiconductor junction located between the first layer and the second layer.

14. The solar cell device of claim 13, wherein the semiconductor junction is a p-i-n junction located in the first layer and the second layer with the nanowires comprising an intrinsic region between the first layer and the second layer.

15. The solar cell device of claim 13, further comprising an encapsulant that partially embeds the bramble layer of nanowires, the encapsulant being an optically transparent insulator material.

16. The solar cell device of claim 13, wherein the bramble layer of nanowires is a nanowire-based antireflector, the nanowire-based antirefector being light absorptive both in a wide band of frequencies and over a wide range of incident angles, such that negligible light is reflected from the solar cell.

17. A method of making a photonic device comprising:
providing a first layer of a microcrystalline material on a substrate surface,
forming a bramble layer of nanowires on the first layer, the nanowires of the bramble layer having first ends integral to crystallites in the first layer and second ends opposite to the first ends, the bramble layer having an uneven contour, different angular orientations of the nanowires in the bramble layer providing the uneven contour; and
providing a second layer of a material on the bramble layer to follow the uneven contour, such that the photonic device has a corresponding uneven surface for capturing photons.

18. The method of making of claim 17, further comprising partially embedding the bramble latter in an encapsulant material before providing the second layer, a portion of the nanowires extending through the encapsulant material, the portion comprising the uneven contour of the bramble layer, the second layer being provided on the encapsulant material and on the bramble layer to contact the portion of the nanowires extending through the encapsulant material.

19. The method of making of claim 17, wherein forming the bramble layer of nanowires comprises growing nanowires on a horizontal surface of the first layer using a metal-catalyzed growth process, such that the second ends of the nanowires comprise a metallic tip.

20. The method of making of claim 17, further comprising providing a semiconductor junction one of in the nanowires, between the first layer and the nanowires, between the second layer and the nanowires, and between the first layer and the second layer.
